(19) United States
(12) Patent Application Publication
(10) Pub. No.: US 2019/0347219 A1
(43) Pub. Date: Nov. 14, 2019

(54) MEMORY DEVICES HAVING A REDUCED GLOBAL DATA PATH FOOTPRINT AND ASSOCIATED SYSTEMS AND METHODS

(71) Applicant: Micron Technology, Inc., Boise, ID (US)

(72) Inventor: Michael V. Ho, Allen, TX (US)

(21) Appl. No.: 15/975,556

(22) Filed: May 9, 2018

(51) Int. Cl. G06F 13/16; G06F 13/40; G11C 7/10; G11C 7/12

(52) U.S. Cl. CPC G06F 13/1668; G11C 7/12; G11C 7/10; G06F 13/4072

(57) ABSTRACT

Memory devices having a reduced global data patch footprint and associated systems and methods. In some embodiments, a memory device is provided, comprising (a) a memory array including first and second sets of memory banks, (b) lower data terminals, (c) upper data terminals, and (d) an input/output (I/O) circuit including an internal data bus. The internal data bus can include a first plurality of global data lines in communication the first set of memory banks, a second plurality of global data lines in communication with the second set of memory banks, a third plurality of global data lines in communication with the first and second pluralities of global data lines, and a fourth plurality of global data lines in communication with the first and second pluralities of global data lines. The third plurality of global data lines is configured to bidirectionally transfer data to and from the lower terminals, and the fourth plurality of global data lines is configured to bidirectionally transfer data to and from the upper terminals.

### TECHNICAL FIELD

The present disclosure is related to memory systems, devices, and associated methods. In particular, the present disclosure is related to memory devices having a reduced global data path footprint.

### BACKGROUND

Memory devices are widely used to store information related to various electronic devices such as computers, wireless communication devices, cameras, digital displays, and the like. Memory devices are frequently provided as internal, semiconductor, integrated circuits and/or external removable devices in computers or other electronic devices. There are many different types of memory, including volatile and non-volatile memory. Volatile memory, including random-access memory (RAM), static random access memory (SRAM), dynamic random access memory (DRAM), and synchronous dynamic random access memory (SDRAM), among others, may require a source of applied power to maintain its data. Non-volatile memory, by contrast, can retain its stored data even when not externally powered. Non-volatile memory is available in a wide variety of technologies, including flash memory (e.g., NAND and NOR), phase change memory (PCM), ferroelectric random access memory (FeRAM), resistive random access memory (RRAM), and magnetic random access memory (MRAM), among others.

Improving memory devices, generally, may include increasing memory cell density, increasing read/write speeds or otherwise reducing operational latency, increasing reliability, increasing data retention, reducing power consumption, or reducing manufacturing costs, among other metrics. One such other metric is reducing the size or footprint of the memory devices and/or components of the memory devices. Many manufacturers achieve size reduction through scaling. Manufacturers can also achieve size reduction through various architectural decisions and/or logic optimizations.

### BRIEF DESCRIPTION OF THE DRAWINGS

FIG. 1 is a block diagram schematically illustrating a memory device configured in accordance with embodiments of the present technology.

FIG. 2 is a block diagram schematically illustrating an input/out circuit configured in accordance with embodiments of the present technology.

FIG. 3 is a schematic view of an internal data bus of a memory device.

FIG. 4 is a schematic view of an internal data bus of a memory device configured in accordance with embodiments of the present technology.

FIG. 5 is a schematic top view of a memory device configured in accordance with embodiments of the present technology.

FIG. 6 is a schematic view of a system that includes a memory device configured in accordance with embodiments of the present technology.

### DETAILED DESCRIPTION

As discussed in greater detail below, the technology disclosed herein relates to memory systems and devices with a reduced global data path footprint. A person skilled in the art, however, will understand that the technology may have additional embodiments and that the technology may be practiced without several of the details of the embodiments described below with reference to the figures indicated below. In the illustrated embodiments below, the memory devices and systems are primarily described in the context of devices incorporating DRAM storage media. Memory devices configured in accordance with other embodiments of the present technology, however, can include other types of memory devices and systems incorporating other types of storage media, including PCM, SRAM, FRAM, RRAM, MRAM, read only memory (ROM), erasable programmable ROM (EPROM), electrically erasable programmable ROM (EEPROM), ferroelectric, magnetoresistive, and other storage media, including non-volatile, flash (e.g., NAND and/or NOR) storage media.

Several memory devices (e.g., DRAM memory devices) use groups of DC and/or power supply lines to shield dynamic signals sent through data lines in the memory devices. In memory devices with wide input/output (I/O) data and high speed operations, these shields are important to preserve and protect signal integrity. Many of these memory devices include multiple I/O circuit configurations to cater to different market segments. Often only one configuration is used, however, meaning that these memory devices carry the remaining configurations as overhead and wasted space. As described in greater detail below, memory devices configured in accordance with embodiments of the present technology use the overhead configurations to replace the shield lines, thereby reducing the size or footprint of global I/O data paths in the memory devices. In addition, these and other memory devices configured in accordance with embodiments of the present technology utilize a staggered firing scheme to separate the transition of signals on the global data lines to reduce coupling within the global data lines that is often caused by simultaneous switching.

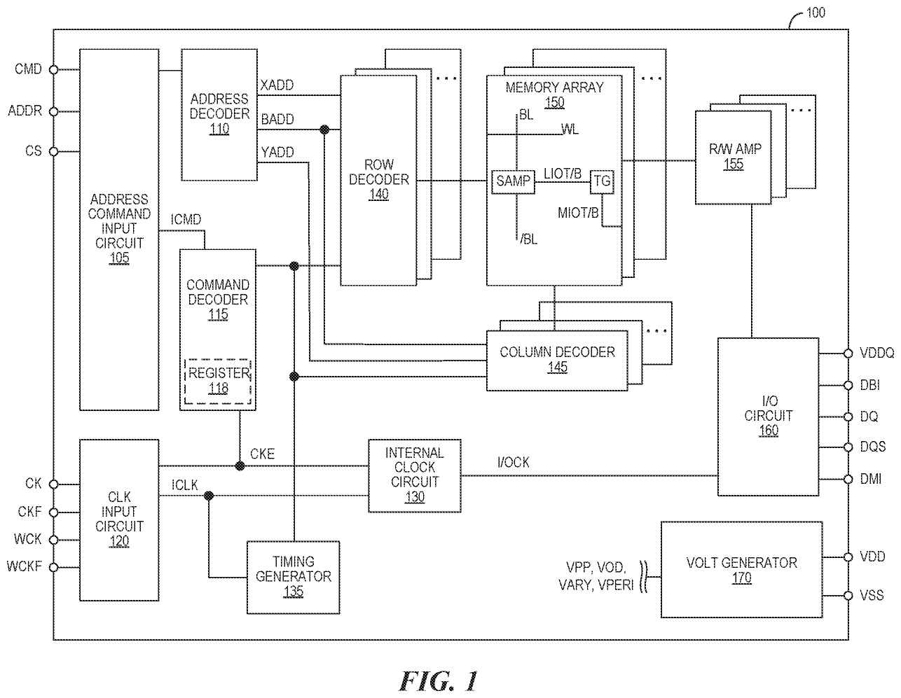

FIG. 1 is a block diagram schematically illustrating a memory device 100 configured in accordance with an embodiment of the present technology. The memory device 100 can be connected to any one of a number of electronic devices capable of utilizing memory for the temporary or persistent storage of information, or a component thereof. For example, a host device of memory device 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to memory device 100, although in other embodiments, the host device may be indirectly connected to memory device (e.g., over a networked connection or through intermediary devices).

As shown in FIG. 1, the memory device 100 may include an array of memory cells, such as memory array 150. The memory array 150 may include a plurality of banks (e.g., banks 0-15 in the example of FIG. 1), and each bank may include a plurality of word lines (WL), a plurality of bit lines (BL), and a plurality of memory cells arranged at intersections of the word lines and the bit lines. Memory cells can include any one of a number of different memory media types, including capacitive, magnetoresistive, ferroelectric, phase change, or the like. The selection of a word line WL may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least respective one main I/O line pair (MIOT/B), via transfer gates (TG), which can function as switches. The memory array 150 may also include plate lines and corresponding circuitry for managing their operation.

The memory device 100 may employ a plurality of external terminals that include command and address terminals coupled to a command bus and an address bus to receive command signals CMD and address signals ADDR, respectively. The memory device may further include a chip select terminal to receive a chip select signal CS, clock terminals to receive clock signals CK, CKF, WCK, and WCKF, data terminals DQ, DQS, DBI, and DMI, and power supply terminals VDD, VSS, VDDQ, and/or VSSQ.

As shown in the illustrated embodiment, the clock terminals may be supplied with external clock signals and complementary external clock signals. The external clock signals CK, CKF, WCK, and WCKF can be supplied to a clock input circuit 120. The CK and CKF signals and the WCK and WCKF signals can be complementary. Complementary clock signals can have opposite clock levels and can transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level, the complementary clock signal transitions from the high clock level to the low clock level; and when the clock signal transitions from the high clock level to the low clock level, the complementary clock signal transitions from the low clock level to the high clock level.

Input buffers included in the clock input circuit 120 can receive the external clock signals. For example, when enabled by a CKE signal from command decoder 115, an input buffer can receive the CK and CKF signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable signal CKE from command/address input circuit 105. For example, the internal clock circuit 130 can include a clock path (not shown in FIG. 1) that receives the internal clock signal ICLK and provides various clock signals to the command decoder 115. The internal clock circuit 130 can further provide I/O clock signals I/OCK. The I/O clock signals I/OCK can be supplied to I/O circuit 160 and can be used as a timing signal for determining an output timing of read data and the input timing of write data. The I/O clock signals I/OCK can be provided at multiple clock frequencies so that data can be output from and input to the memory device 100 at different data rates. A higher clock frequency may be desirable when high memory speed is desired. A lower clock frequency may be desirable when lower power consumption is desired. The internal clock signals ICLK can also be supplied to a timing generator 135 and thus various internal clock signals can be generated.

The command terminals and address terminals may be supplied with an address signal and a bank address signal from outside. The address signal and the bank address signal supplied to the address terminals can be transferred, via the command/address input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal (BADD) and supply the bank address signal to both the row decoder 140 and the column decoder 145.

The command and address terminals may be supplied with command signals CMD, address signals ADDR, and chip selection signals CS, from a memory controller. The command signals may represent various memory commands from the memory controller (e.g., including access commands, which can include read commands and write commands). The select signal CS may be used to select the memory device 100 to respond to commands and addresses provided to the command and address terminals. When an active CS signal is provided to the memory device 100, the commands and addresses can be decoded and memory operations can be performed. The command signals CMD may be provided as internal command signals ICMD to the command decoder 115 via the command/address input circuit 105. The command decoder 115 may include circuits to decode the internal command signals ICMD to generate various internal signals and commands for performing memory operations, for example, a row command signal to select a word line and a column command signal to select a bit line. The internal command signals can also include output and input activation commands, such as clocked command. The command decoder 115 may further include one or more registers 118 for tracking various counts or values.

The power supply terminals may be supplied with power supply potentials VDD and VSS. These power supply potentials VDD and VSS can be supplied to an internal voltage generator circuit 170. The internal voltage generator circuit 170 can generate various internal potentials VPP, VOD, VARY, VPERI, and the like based on the power supply potentials VDD and VSS. The internal potential VPP can be used in row decoder 140, the internal potentials VOD and VARY can be used in sense amplifiers included in memory array 150, and the internal potential VPERI can be used in many other circuit blocks.

The power supply terminal may also be supplied with power supply potential VDDQ and/or VSSQ. The power supply potential VDDQ can be supplied to I/O circuit 160 together with the power supply potential VSS. The power supply potential VDDQ can be the same potential as the power supply potential VDD in an embodiment of the present technology. The power supply potential VDDQ can be a different potential from the power supply potential VDD in another embodiment of the present technology. However, the dedicated power supply potential VDDQ can be used for the input/output circuit 160 so that power supply noise generated by the input/output circuit 160 does not propagate to the other circuit blocks.

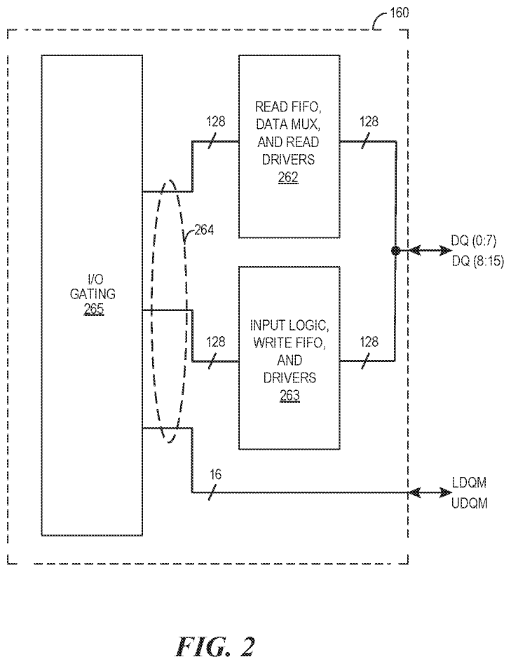

FIG. 2 is a block diagram schematically illustrating the I/O circuit 160 of the memory device 100 configured in accordance with embodiments of the present technology. Well-known structures and functions of the I/O circuit 160 have not been shown or described in detail in FIG. 2 to avoid unnecessarily obscuring particular aspects of the present technology. Referring to FIGS. 1 and 2 together, when a read command is issued and a row address and a column address are timely supplied with the read command, read data can be read from memory cells in the memory array 150 (FIG. 1) designated by the row address and column address. The read command may be received by the command decoder 115 (FIG. 1), which can provide internal commands to the I/O circuit 160 so that read data can be output from data terminals via read/write amplifiers 155 (FIG. 1) and the I/O circuit 160. More specifically, the read data can be output via the read/write amplifiers 155 and I/O gating 265 (FIG. 2) onto global data lines of an internal data bus 264 (FIG. 2) within the I/O circuit 160. The global data lines of the internal data bus 264 can transfer the read data through a read FIFO, a data multiplexer, read drivers 262 (FIG. 2) and/or through other circuits and/or components (not shown) of the I/O circuit 160 to the data terminals DQ(0:7), DQ(8:15), LDQM, UDQM, DQS (FIG. 1), DBI (FIG. 1), and/or DMI (FIG. 1) according to the I/OCK clock signal.

The read data may be provided at a time defined by read latency information that can be programmed in the memory device 100, for example, in a mode register (not shown in FIG. 1 or 2). The read latency information can be defined in terms of clock cycles of the CK clock signal (FIG. 1). For example, the read latency information can be a number of clock cycles of the CK signal after the read command is received by the memory device 100 when the associated read data is provided.

When a write command is issued and a row address and a column address are timely supplied with the command, write data can be supplied to the data terminals DQ(0:7), DQ(8:15), LDQS, UDQS, LDQM, UDQM, DBI, and/or DMI according to the I/OCK clock signal. The write command may be received by the command decoder 115 (FIG. 1), which can provide internal commands to the I/O circuit 160 so that the write data can be received by data receivers in the input/output circuit 160, and supplied via the input/output circuit 160 and the read/write amplifiers 155 (FIG. 1) to the memory array 150 (FIG. 1). More specifically, the write data can be transferred via the global data lines of the internal data bus 264 through input logic, a write FIFO, write drivers 263 (FIG. 2) and/or other circuits and/or components (not shown) of the I/O circuit 160, through I/O gating 265 (FIG. 2), and/or through the read/write amplifiers 155 to the memory array 150.

The write data may be written in the memory cell designated by the row address and the column address. The write data may be provided to the data terminals at a time that is defined by write latency information. The write latency information can be programmed in the memory device 100, for example, in the mode register (not shown in FIG. 1 or 2). The write latency information can be defined in terms of clock cycles of the CK clock signal. For example, the write latency information can be a number of clock cycles of the CK signal after the write command is received by the memory device 100 when the associated write data is received.

As discussed above, the global data lines are bi-directional signal paths that carry read and/or write data from and/or to the memory array 150 (FIG. 1) and/or the data terminals DQ(0:7) and/or DQ(8:15) (FIG. 2) of the memory device 100. For a DDR4 memory device, each data terminal DQ0-DQ15 operates in a burst of eight bits for a total of 128 global data lines. The I/O circuit also includes 16 data mask lines (one data mask line per eight global data lines) that carry signals from data mask terminals LDQM and UDQM to the I/O gating 265. The data mask lines are used to suppress data input/output of the memory device 100. For example, when a data mask line is asserted in a first state (e.g., in a high state), data on the corresponding global data lines is not written to the memory array 150 and/or is not output from the data terminals DQ(0:7) and/or DQ(8:15).

Depending on the configuration of the memory device 100, all or a subset of the global data lines and/or the data mask lines on the internal data bus 264 are used. For example, in an ×16 configuration of the memory device 100, all of the data terminals DQ(0:7) and DQ(8:15), the 128 corresponding global data lines, both data mask terminals LDQM and UDQM, and the 16 corresponding data mask lines are used. In ×4 and/or ×8 configurations of the memory device 100, on the other hand, only the lower data terminals DQ(0:7), the 64 corresponding global data lines, the lower data mask terminal LDQM, and/or the eight corresponding data mask lines are used. In these configurations, the data mask lines corresponding to the upper data mask terminal UDQM can be tied to a first state (e.g., a high state) to mask activity on the portion of the internal data bus 264 corresponding to the upper data terminals DQ(8:15). A single memory device can be configured to support each of the ×16, ×8 and ×4 configurations.

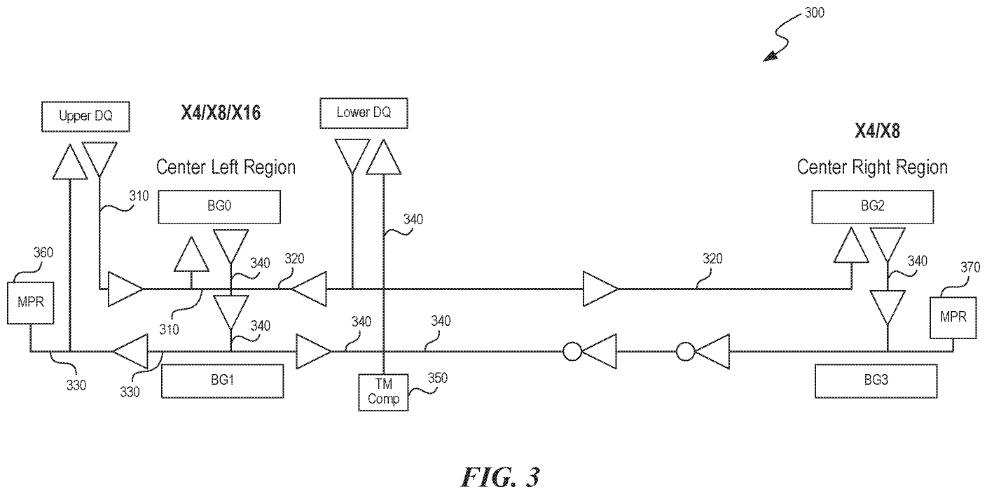

FIG. 3 is a schematic view of a global data path on an internal data bus of a memory device 300 (“device 300”). During read and/or write operations, data bits are transmitted one at a time to the center of the device 300 according to edge(s) of the input/output clock signal I/OCK. At the center of the device 300, the data bits are lined up and then routed to one or more memory bank groups (“BGs”) in the memory array 150 (FIG. 1) and/or to the data terminals DQ(0:7) and/or DQ(8:15) (e.g., according to a zero to parallel operation). As shown in FIG. 3, the device 300 includes a two-center architecture having a “Center Left” region and a “Center Right” region, and a plurality of global data lines for transferring data from the BGs (e.g., BG0, BG1, BG2, BG3) of the memory array 150 (FIG. 1) to the lower data terminals (“Lower DQ”) and upper data terminals (“Upper DQ”). The global data lines include (a) a first plurality of global data lines 310 for transferring read-only data from the upper data terminals of the device 300 to a bank group (e.g., BG0), (b) a second plurality of global data lines 320 for transferring write-only data from the lower data terminals to multiple bank groups (e.g., BG0, BG2) of the device 300, (c) a third plurality of global data lines 330 for transferring read-only multipurpose register data (“MPR”) to the upper data terminals of the device 300, and (d) a fourth plurality of global data lines 340 for transferring write-only data from multiple bank groups (e.g., BG0, BG1, BG2, BG3) to the lower data terminals of the device 300. Each of the first, second, third and fourth pluralities of global data lines 310, 320, 330, 340 are mono-directional and represents 72 data lines, which can include, for example, 64 data lines and 8 data masks. Notably, the control logic (not shown) used to control the “Center Left” region of the two-center architecture is independent of the control logic (not shown) used to control the “Center Right” region. As a result, the two-center architecture shown in FIG. 3 can require significant power consumption, as the device 300 must operate duplicative circuitry. As also shown in FIG. 3, the device 300 further includes a test mode data block 350 including compressed test mode data and test mode logic, and multiple MPR data blocks 360, 370 each including MPR data and MPR logic. The test mode data is used to check and compare data in memory arrays to input/output data. As shown in the illustrated embodiment, the MPR data blocks 360, 370 and test mode data block 350 are each separate lines that are in addition to the first, second, third and fourth pluralities of global data lines 310, 320, 330, 340 previously described. In some embodiments, each of the MPR data blocks 360, 370 can correspond to 32 individual MPR data lines and the test mode data block 350 can correspond to 20 test mode data lines. The test mode data streams 350 and MPR data streams 360, 370 are combined with the other data (e.g., read and write data) and routed to the lower and upper terminals. Notably, for the device 300, the test mode and MPR data are treated the same as read and write data, in that the read, write, test mode and MPR data are sent to the lower and upper terminals without any prioritization.

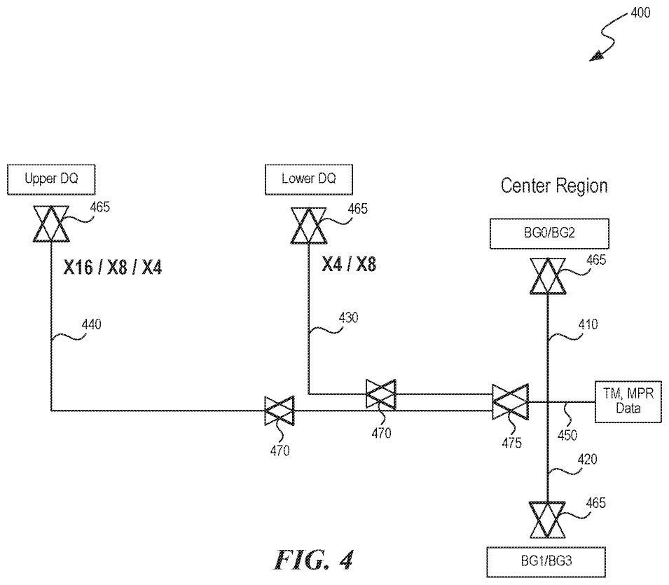

FIG. 4 is a schematic view of an internal data bus on a memory device 400 (“device 400”) configured in accordance with embodiments of the present technology. As shown in the illustrated embodiment, the device 400 represents a single-center architecture and includes a plurality of BGs (e.g., BG0, BG1, BG2, BG3), lower data terminals (“lower DQ”), upper data terminals (“upper DQ”), and a plurality of global data lines. The plurality of global data lines can include (a) a first plurality of global data lines 410 corresponding to and in communication with a first set of the bank groups (e.g., BGO/BG2), (b) a second plurality of global data lines 420 corresponding to and in communication with a second set of the bank groups (e.g., BG1/BG3) different than the first set of bank groups, (c) a third plurality of global data lines 430 in communication with each of the first and the second pluralities of global data lines 410, 420, and (d) a fourth plurality of global data lines 440 also in communication with each of the first and the second pluralities of global data lines 410, 420. The third plurality of global data lines 430 is configured to bidirectionally transfer data to and from the lower terminals, and the fourth plurality of local data lines 440 is configured to bidirectionally transfer data to and from the upper terminals. Stated differently, the third plurality of global data lines 430 is configured to transfer data from the first and second pluralities of global data lines 410, 420 to the lower terminals, and the fourth plurality of global data lines 440 is configured to transfer data from the first and second pluralities of global data lines 410, 420 to the upper terminals. As such, the third and fourth pluralities of global data lines 430, 440 are each configured to transfer data having read and write functionality from the first and second pluralities of global data lines 410, 420. Each of the first, second, third and fourth pluralities of global data lines 410, 420, 430, 440 represent 72 data lines, which can include, for example, 64 data lines and 8 data masks.

As shown in the illustrated embodiment, the device 400 can further include a fifth plurality of global data lines 450. In some embodiments, the fifth plurality of global data lines 450 can be used to incorporate other data, such as test mode data (e.g., compressed test mode data) and/or MPR data (e.g., MPR read data), onto the plurality of global data lines, and route them to the lower and upper terminals. The test mode data and/or MPR data on the fifth plurality of global data lines 450 can be separately controlled (e.g., by shared control logic with the other global data lines) and routed at appropriate times to their corresponding destinations. In some embodiments, the test mode data and/or MPR data on the fifth plurality of global data lines 450 can be transferred to their corresponding target destinations via shared global data lines along with other read and write data. The ability to share the global data lines amongst the MPR data, test mode data, and read and write data decreases the number of data lines needed for the device 400, thereby limiting the amount of space on the device 400 occupied by data lines. Furthermore, because the test mode data and/or MPR data is often not time sensitive, or at least not as time sensitive as the read and write data, the data of the fifth plurality of global data lines 450 can be controlled to be routed to the third and fourth pluralities of global data lines 430, 440, for example, only after the read and write data has been sent. Compared the device 300 described above, the fifth plurality of global data lines 450 can improve timing and routing conditions by ensuring that read and write data is prioritized over test mode and/or MPR data.

As further shown in the illustrated embodiment, the device 400 can include one or more multiplexers 475 positioned between (a) the first, second and fifth pluralities of global data lines 410, 420, 450 and (b) the third and fourth pluralities of global data lines 430, 440. The multiplexers 475 can multiplex (e.g., time multiplex) data from the first, second, and/or fifth pluralities of global data lines 410, 420, 450 onto the third and/or fourth pluralities of global data lines 430, 440 (i.e., from the memory array to the lower and/or upper terminals). As shown in the illustrated embodiment, the multiplexers 475 can also multiplex data being transferred in the opposite direction. That is, the multiplexers 475 can multiplex data coming from the third and/or fourth pluralities of global data lines 430, 440 onto the first, second and/or fifth pluralities of global data lines 410, 420, 450 (i.e., from the lower and/or upper terminals to the memory array). In some embodiments, individual signals having data can be grouped together in a phase or group of signals, and the group can be multiplexed onto individual lines of the third and fourth pluralities of global data lines 430, 440, or onto individual lines of the first, second and/or fifth pluralities of global data lines 410, 420, 450, in route to their target destinations. The individual signals can then be demultiplexed upon reaching their target destinations. By multiplexing multiple signals at once onto individual lines of the first, second, third, fourth and/or fifth pluralities of global data lines 410, 420, 430, 440, 450, the number of global data lines of the device 400 can be significantly reduced compared to, for example, the number of global data lines needed to operate device 300. As shown in the illustrated embodiment, the device 400 can also include one or more repeaters 470 and drivers 465. Each of the repeaters 470 and drivers 465 are configured to support monodirectional and bidirectional data transmission. As such, the number of repeaters 470 and drivers 465 needed for the device 400 can be significantly reduced compared to the numbers of repeaters and drivers needed for device 300.

As noted above, the device 400 includes a single-center architecture having a “Center” region. To control the transfer of data amongst the first and second pluralities of global data lines 410, 420 and the third and fourth pluralities of global data lines 430, 440, the device 400 utilizes a common control logic (not shown) located at or near the “Center” region. The control logic can utilize timing controls, as well as speed and power design criteria of the device 400, to optimize data transfer throughout the device 400. For example, the control logic can prioritize certain data streams (e.g., data having read and write functionality) over other data streams (e.g., test mode data and/or MPR data) that have less time criticality. In some embodiments, the control logic can further include combining individual signals into a group of signals that is multiplexed onto one of the global data lines and then demultiplexed at target destinations of the individual signals.

Embodiments of the present technology have multiple advantages over other devices previously used for data transfer on memory devices. For example, compared to the device 300 described above, the device 400 reduces the number of global data lines by allowing each of the global data lines to operate bidirectionally and transfer both read and write data on the same line. By reducing the number of global data lines on the device 400, and therein reducing the global data path for a particular data stream, the device 400 can be made smaller. Additionally, by orienting the first and second pluralities of global data lines 410, 420 in a center region of the device 400, control logic can be shared between the first and second pluralities of global data lines 410, 420, as well as between the third and fourth pluralities of global data lines 430, 440. This shared control logic allows for more efficient data routing, which can result in faster routing and less power output.

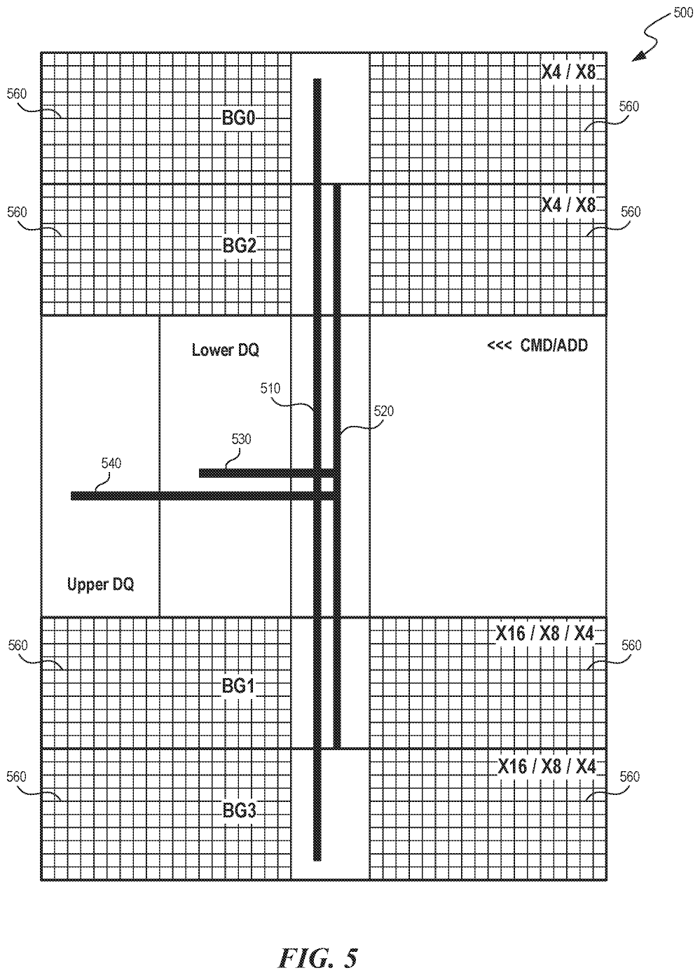

FIG. 5 is a schematic view of a memory device 500 configured in accordance with embodiments of the present technology. As shown in the illustrated embodiment, the device 500 includes (a) a first plurality of global data lines 510 corresponding to and in communication with the first set of bank groups BG0/BG2, (b) a second plurality of global data lines 520 corresponding to and in communication with the second set of bank groups BG1/BG3, (c) a third plurality of global data lines 530 in communication with the lower data terminals (“Lower DQ”) and each of the first and the second pluralities of global data lines 510, 520, and (d) a fourth plurality of global data lines 540 in communication with the upper data terminals (“Upper DQ”) and each of the first and second pluralities of global data lines 510, 520. In some embodiments, each of the first, second, third and fourth pluralities of global data lines 510, 520, 530, 540 can correspond to (e.g., be identical to) the first, second, third and fourth pluralities of global data lines 410, 420, 430, 440, respectively, described with reference to FIG. 4. As also shown in the illustrated embodiment, each of the bank groups BG0, BG1, BG2, BG3 includes a plurality of local data lines 560 for transferring data from the memory array 150 (FIG. 1) to the global data lines and then to the lower and upper terminals. In some embodiments, including the illustrated embodiment, the lower and upper terminals are both positioned on the same side of the center region where the first and second pluralities of global data lines extend. Such a positioning causes the third plurality and the fourth plurality of global data lines 530, 540 to extend from the “Center” region in the same direction, thereby allowing the fourth plurality of global data lines 540 to shield the third plurality of global data lines 530. In such embodiments, the device 500 does not need to include additional shielding lines, which are often needed in conventional devices. As such, the lack of additional shielding lines thereby allows the device 500 to be made smaller because less shield lines are needed. As further shown in the illustrated embodiment, each of the first set of bank groups BG0/BG2 and the second set of bank groups BG1/BG3 are arranged in a horizontal orientation. In some embodiments, such an orientation can allow each set of bank groups to share logic and local routing, thereby further resulting in a reduction of power consumption and overall data path length.

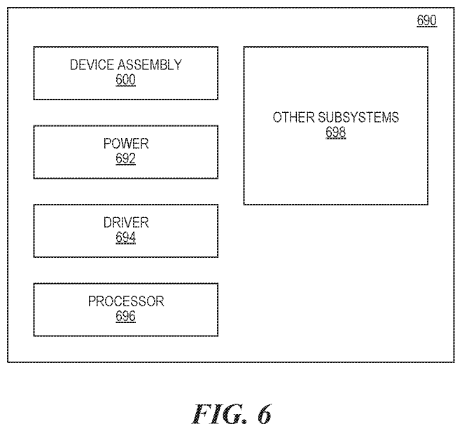

FIG. 6 is a schematic view of a system that includes a memory device in accordance with embodiments of the present technology. Any one of the foregoing memory devices described above with reference to FIGS. 1, 2, 4 and 5 can be incorporated into any of a myriad of larger and/or more complex systems, a representative example of which is system 690 shown schematically in FIG. 5. The system 690 can include a semiconductor device assembly 600, a power source 692, a driver 694, a processor 696, and/or other subsystems and components 698. The semiconductor device assembly 500 can include features generally similar to those of the memory device described above with reference to FIGS. 1, 2, 4 and 5, and can, therefore, include various features of memory content authentication. The resulting system 690 can perform any of a wide variety of functions, such as memory storage, data processing, and/or other suitable functions. Accordingly, representative systems 690 can include, without limitation, hand-held devices (e.g., mobile phones, tablets, digital readers, and digital audio players), computers, vehicles, appliances, and other products. Components of the system 690 may be housed in a single unit or distributed over multiple, interconnected units (e.g., through a communications network). The components of the system 690 can also include remote devices and any of a wide variety of computer readable media.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those of ordinary skill in the relevant art will recognize. For example, although steps are presented in a given order, alternative embodiments may perform steps in a different order. The various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the terms “comprising,” “including,” “having,” and “with” are used throughout to mean including at least the recited feature(s) such that any greater number of the same feature and/or additional types of other features are not precluded.

From the foregoing, it will also be appreciated that various modifications may be made without deviating from the disclosure. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described.

1. A memory device, comprising:
a memory array having a first set of memory banks and a second set of memory banks different than the first set;
lower data terminals;
upper data terminals; and
an input/output (I/O) circuit including an internal data bus electrically coupling each of the lower and the upper data terminals to the memory array,
wherein the internal data bus includes—
a first plurality of global data lines in communication with the first set of memory banks,
a second plurality of global data lines corresponding to the second set of memory banks,
a third plurality of global data lines in communication with the first and the second pluralities of global data lines, wherein the third plurality of global data lines are configured to bidirectionally transfer data (a) from the first and/or second plurality of global data lines to the lower and/or upper terminals, and (b) from the lower and/or upper terminals to the first and/or second plurality of global data lines, and
a fourth plurality of global data lines in communication with the first and the second plurality of global data lines, wherein the fourth plurality of global data lines are configured to bidirectionally transfer data (a) from the first and/or second plurality of global data lines to the lower and/or upper terminals, and (b) from the lower and/or upper terminals to the first and/or second plurality of global data lines,
wherein:
individual lines of the fourth plurality of global data lines are interleaved with and abutting at least a portion of individual lines of the third plurality of global data lines.

2. The memory device of claim 1, further comprising common control logic configured to control data communication amongst the third plurality of global data lines and the fourth plurality of global data lines.

3. The memory device of claim 2 wherein the control logic controls data communication by multiplexing data from individual lines of the first and second pluralities of global data lines onto the individual lines of the third and fourth pluralities of global data lines.

4. The memory device of claim 1 wherein the internal data bus further includes a fifth plurality of global data lines associated with test mode data and/or multipurpose register data, wherein the fifth plurality of global data lines is in communication with each of the third plurality and the fourth plurality of global lines.

5. The memory device of claim 1 wherein the individual lines of the third plurality and the individual lines of the fourth plurality of global lines are each configured to bidirectionally transfer read data and write data using a plurality of bidirectional repeaters.

6. The memory device of claim 1 wherein the individual lines of the third plurality and the individual lines of the fourth plurality of global lines are each configured to bidirectionally transfer read data and write data using a plurality of bidirectional drivers.

7. The memory device of claim 1 wherein the individual lines of the fourth plurality of global data lines are configured to function as shields for the individual lines of the third plurality of global data lines, and the individual lines of the third plurality of global data lines are configured to function as shields for the fourth plurality of global data lines.

8. The memory device of claim 1 wherein the internal data bus does not include any global data lines used solely for shielding.

9. The memory device of claim 1 wherein the third plurality and the fourth plurality of global data lines together comprise 144 data lines.

10. The memory device of claim 1 wherein the first plurality and the second plurality of global data lines are positioned based on a single center architecture.

11. The memory device of claim 1 wherein the first plurality and the second plurality of global data lines are positioned in a center region of the memory device, and wherein the lower and upper data terminals are positioned on a first side of the center region such that the third plurality and the fourth plurality of global data lines each extend from the center region toward the upper and lower terminals in the same direction.

12. The memory device of claim 1 wherein the first set of memory banks share a first common control logic, and the second set of memory banks share a second common control logic.

13. The memory device of claim 2 wherein each of the third and the fourth plurality of global data lines are shorter in length than each of the first plurality and the second plurality of global data lines.

14. A memory system, comprising:
a host device; and
a memory device including—
a memory array having multiple memory banks; and
an input/output (I/O) circuit including—
a first plurality of global data lines in communication with at least a portion of the memory banks,
a second plurality of global data lines in communication with at least a portion of memory banks,
a third plurality of global data lines in communication with the first and the second pluralities of global data lines, wherein the third plurality of global data lines are configured to bidirectionally transfer data (a) from the first and/or second plurality of global data lines to the lower and/or upper terminals, and (b) from the lower and/or upper terminals to the first and/or second plurality of global data lines, and
a fourth plurality of global data lines in communication with the first and the second plurality of global data lines, wherein the fourth plurality of global data lines are configured to bidirectionally transfer data (a) from the first and/or second plurality of global data lines to the lower and/or upper terminals, and (b) from the lower and/or upper terminals to the first and/or second plurality of global data lines,
wherein:
individual lines of the fourth plurality of global data lines are interleaved with and abutting at least a portion of individual lines of the third plurality of global data lines.

15. The memory device of claim 14 wherein the I/O circuit further includes a fifth plurality of global data lines associated with compressed test mode data and multipurpose register data, wherein the fifth plurality of global data lines is in communication with the individual lines of the third plurality and the fourth plurality of global lines via one or more multiplexers.

16. The memory device of claim 15, further comprising common control logic configured to steer data of the fifth plurality of global data lines onto the individual lines of the third plurality of global data lines and/or the fourth plurality of global data lines.

17. The memory device of claim 14, further comprising common control logic configured to control data communication between (a) one or more of the first plurality and the second plurality of global data lines, and (b) one or more of the third plurality and the fourth plurality of global data lines.

18. A method for operating a memory device, the method comprising:
electrically coupling an internal data bus of an input/output circuit to lower data terminals and upper data terminals of the memory device, the internal data bus including—
a first plurality of global data lines in communication with one or more memory banks of the memory device,
a second plurality of global data lines in communication with one or more of the memory banks,
a third plurality of global data lines in communication with the first plurality and the second plurality of global data lines, wherein individual lines of the third plurality of global data lines are configured to bidirectionally transfer data, and
a fourth plurality of global data lines in communication with the first plurality and the second plurality of global data lines, wherein individual lines of the fourth plurality of global data lines are configured to bidirectionally transfer data; and
transferring data on the third plurality of global data lines (a) from one or more of the memory banks to the lower and/or upper terminals through the first and/or second plurality of global data lines, and (b) from the lower and/or upper terminals to one or more of the memory banks through the first and/or second plurality of global data lines; and
transferring data on the fourth plurality of global data lines (a) from one or more of the memory banks to the lower and/or upper terminals through the first and/or second plurality of global data lines, and (b) from the lower and/or upper terminals to one or more of the memory banks through the first and/or second plurality of global data lines,
wherein:
transferring the data on the third plurality of global data lines and/or transferring the data on the fourth plurality of global data lines includes transferring the data according to a staggered firing scheme to separate transition of corresponding signals in time.

19. The method of claim 18 wherein transferring data on the third plurality of global data lines includes multiplexing data onto individual lines of third plurality of global data lines, and wherein transferring data on the fourth plurality of global data lines includes multiplexing data onto individual lines of fourth plurality of global data lines.

20. The method of claim 19 wherein the data being multiplexed onto the individual lines of the third plurality and the fourth plurality of global data lines includes test mode data and multipurpose register data.

21. The method of claim 18, further comprising controlling the data transfer on individual lines of the third plurality and the fourth plurality of global data lines via a common control logic, wherein the common control logic routes data from the first plurality and the second plurality of global data lines onto the individual lines of the third plurality and/or the fourth plurality of global data lines.

22. The memory device of claim 2, wherein the common control logic is configured to utilize a staggering firing scheme to separate transitions of signals across time for the data communication for reducing coupling within the global data lines caused by simultaneous switching.

23. The memory device of claim 17, wherein the common control logic is configured to utilize a staggering firing scheme to separate transitions of signals across time for the data communication for reducing coupling within the global data lines caused by simultaneous switching.
